(19) United States
(12) Patent Application Publication
(10) Pub. No.: US 2013/0160794 A1
(43) Pub. Date: Jun. 27, 2013

(54) METHODS AND APPARATUS FOR CLEANING SUBSTRATE SURFACES WITH ATOMIC HYDROGEN

(71) Applicant: Applied Materials, Inc., Santa Clara, CA (US)

(72) Inventors: JOE GRIFFITH CRUZ, San Jose, CA (US); JEONGWON PARK, Palo Alto, CA (US); PRAVIN K. NARWANKAR, Sunnyvale, CA (US); NATE SI NGUYEN, Fountain Valley, CA (US); HANH NGUYEN, San Jose, CA (US); TO CHAN, Fremont, CA (US); JINGJING XU, Cupertino, CA (US)

(73) Assignee: APPLIED MATERIALS, INC., Santa Clara, CA (US)

(21) Appl. No.: 13/723,409

(22) Filed: Dec. 21, 2012

Related U.S. Application Data
(60) Provisional application No. 61/579,830, filed on Dec. 23, 2011.

(51) Int. Cl. B08B 7/00; H01L 21/02

(52) U.S. Cl. CPC B08B 7/00; H01L 21/02041
USPC 134/1.1; 156/345.33; 156/345.29; 156/345.43

(57) ABSTRACT

Methods and apparatus for cleaning substrate surfaces are provided herein. In some embodiments, a method of cleaning a surface of a substrate may include providing a hydrogen containing gas to a first chamber having a plurality of filaments disposed therein; flowing a current through the plurality of filaments to raise a temperature of the plurality of filaments to a process temperature sufficient to decompose at least some of the hydrogen containing gas; and cleaning the surface of the substrate by exposing the substrate to hydrogen atoms formed from the decomposed hydrogen containing gas for a period of time.

### CROSS-REFERENCE TO RELATED APPLICATIONS

This application claims benefit of U.S. provisional patent application Ser. No. 61/579,830, filed Dec. 23, 2011, which is herein incorporated by reference.

### FIELD

Embodiments of the present invention generally relate to semiconductor substrate processing, and more particularly, to methods for cleaning a substrate surface.

### BACKGROUND

Semiconductor device fabrication requires multiple process steps to complete a finished device. However, process steps or intervening conditions may produce unwanted materials (e.g., native oxide layers, contaminants, residues, or the like) that may deposit or form on surfaces of the substrate. Such materials are typically removed via substrate cleaning processes. Conventional substrate cleaning processes typically include exposing a substrate to a plasma formed from a process gas (e.g. a fluorine containing gas) under high temperate and/or pressure. However, the inventor has observed that exposing a substrate to the plasma under such process conditions may result unacceptable damage to the substrate.

Therefore, the inventor has provided improved methods of cleaning substrate surfaces.

### SUMMARY

Methods and apparatus for cleaning substrate surfaces are provided herein. In some embodiments, a method of cleaning a surface of a substrate may include providing a hydrogen containing gas to a first chamber having a plurality of filaments disposed therein; flowing a current through the plurality of filaments to raise a temperature of the plurality of filaments to a process temperature sufficient to decompose at least some of the hydrogen containing gas; and cleaning the surface of the substrate by exposing the substrate to hydrogen atoms formed from the decomposed hydrogen containing gas for a period of time.

In some embodiments, a substrate cleaning system may include a process chamber having an internal volume; a substrate support disposed in the internal volume of the process chamber to support a substrate to be cleaned in the process chamber; an atomic hydrogen source configured to provide atomic hydrogen to the surface of the substrate during operation, the atomic hydrogen source comprising a plurality of filaments and a terminal to couple the plurality of filaments to a power source to heat the plurality of filaments to a temperature sufficient to produce atomic hydrogen from a hydrogen gas; and a hydrogen gas source coupled to the atomic hydrogen source to provide hydrogen gas to the atomic hydrogen source.

Other and further embodiments of the present invention are described below.

### BRIEF DESCRIPTION OF THE DRAWINGS

Embodiments of the present invention, briefly summarized above and discussed in greater detail below, can be understood by reference to the illustrative embodiments of the invention depicted in the appended drawings. It is to be noted, however, that the appended drawings illustrate only typical embodiments of this invention and are therefore not to be considered limiting of its scope, for the invention may admit to other equally effective embodiments.

FIG. 1 is a flow diagram of a method for cleaning a substrate surface in accordance with some embodiments of the present invention.

FIGS. 2A-B are illustrative cross-sectional views of a substrate during different stages of the method of FIG. 1 in accordance with some embodiments of the present invention.

FIG. 3 is a processing system suitable for performing the methods depicted in FIG. 1 in accordance with some embodiments of the present invention.

FIG. 3A is a processing system suitable for performing the methods depicted in FIG. 1 in accordance with some embodiments of the present invention.

FIG. 4 is an illustrative cross-sectional view of an atomic hydrogen source coupled to a process chamber suitable for performing the methods depicted in FIG. 1 in accordance with some embodiments of the present invention.

FIG. 5 depicts a configuration of filaments suitable for use in an atomic hydrogen source in accordance with some embodiments of the present invention.

FIG. 6 depicts a configuration of filaments suitable for use in an atomic hydrogen source in accordance with some embodiments of the present invention.

FIG. 7 depicts a configuration of filaments suitable for use in an atomic hydrogen source in accordance with some embodiments of the present invention.

FIG. 8 depicts a configuration of filaments suitable for use in an atomic hydrogen source in accordance with some embodiments of the present invention.

To facilitate understanding, identical reference numerals have been used, where possible, to designate identical elements that are common to the figures. The figures are not drawn to scale and may be simplified for clarity. It is contemplated that elements and features of one embodiment may be beneficially incorporated in other embodiments without further recitation.

### DETAILED DESCRIPTION

Methods and apparatus for cleaning surfaces of a substrate are provided herein. Embodiments of the inventive process may advantageously allow for removal of contaminants or undesired layers from a substrate while causing less damage to the substrate as compared to conventional cleaning processes utilizing, for example, one or more of a plasma, a high temperature treatment or a fluorine based chemistry. Moreover, the inventor has observed that by utilizing an appropriately configured chamber to produce atomic hydrogen (e.g., a chamber having a hot wire source, such as a hot wire processing chamber, a hot wire chemical vapor deposition (HWCVD) chamber or similar chamber as described below), a higher density population of atomic hydrogen (e.g., such as 1.3 to about 3 times higher) may advantageously be produced, as compared to methods conventionally used in the semiconductor industry to produce atomic hydrogen. Although not limiting of the scope of application of the inventive methods disclosed herein, the inventive methods have been shown to be particularly effective for the cleaning of larger scale substrates for very large scale integration (VLSI) devices, for example, such as 300 mm substrates, about 1000 mm×1250 mm substrates, about 2200 mm×2500 mm substrates, or greater.

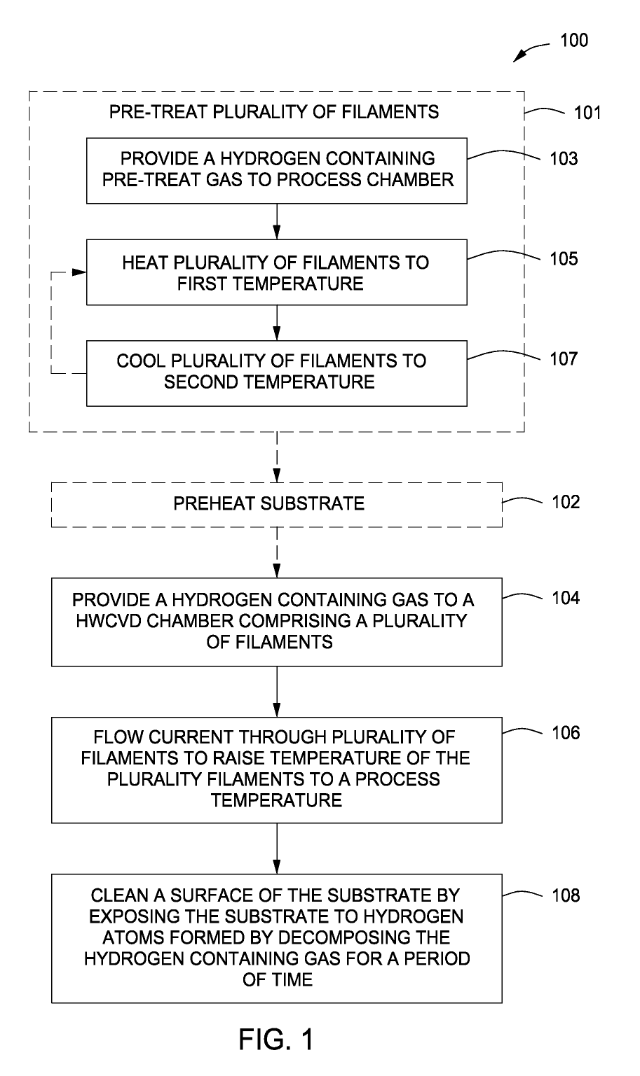

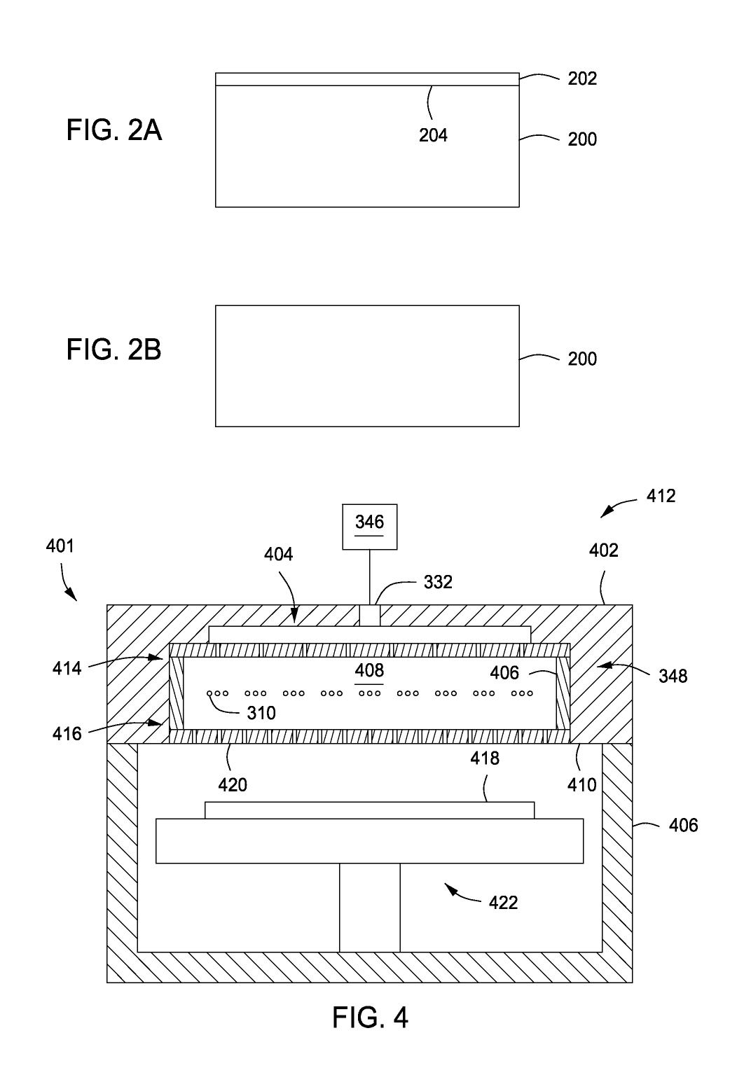

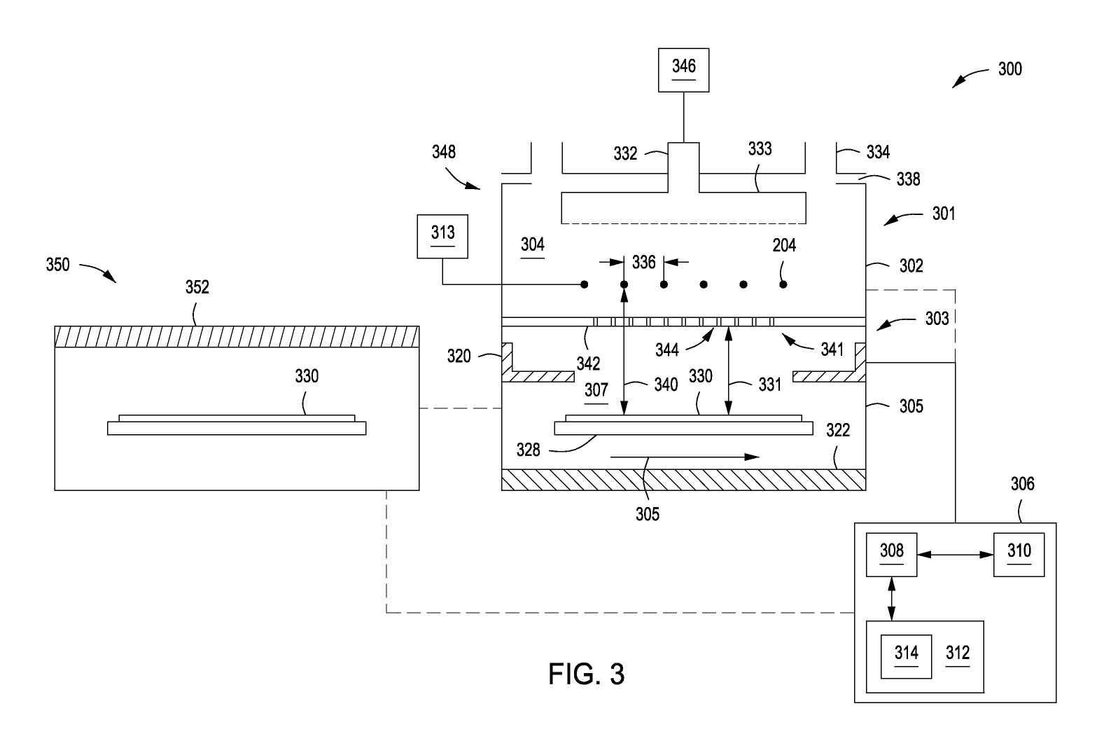

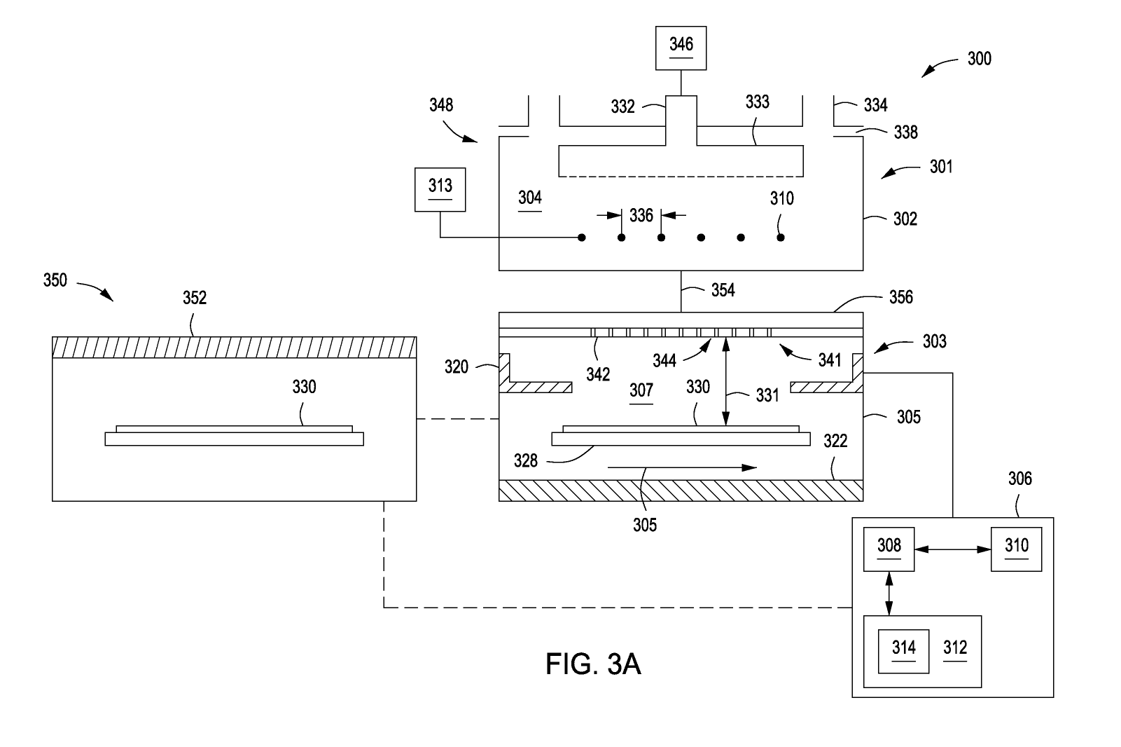

FIG. 1 is a flow diagram of a method 100 for cleaning a substrate surface in accordance with some embodiments of the present invention. FIGS. 2A-B are illustrative cross-sectional views of the substrate during different stages of the processing sequence of FIG. 1 in accordance with some embodiments of the present invention. The inventive methods may be performed in any apparatus suitable for processing semiconductor substrates in accordance with embodiments of the present invention, such as the apparatus discussed below with respect to FIG. 3.

The inventors have observed that in process chambers utilizing filaments as a heat and/or energy source, for example, such as hot wire processing chambers (e.g., a HWCVD chamber or other suitable chamber having a hot wire source), the filaments may be fabricated from materials that are unstable or susceptible to deterioration. Due to this instability, such materials may outgas contaminants (e.g. impurities in the material) or form particles that may settle on a substrate during processing, thereby negatively impacting performance characteristics of the fabricated device, for example such as high device leakage current, on/off ratio, threshold voltage shifts, or the like. Such negative impacts are exacerbated as dimensions of the device interconnections shrink (e.g., device interconnections less than or equal to about 20 nanometers).

In some embodiments, the method 100 may optionally begin at 101 where a plurality of filaments disposed in a process chamber (e.g., the plurality of filaments 310 of the process chamber 300 described below) may be optionally pre-treated. Pre-treating the plurality of filaments prior to performing a cleaning process (e.g., the cleaning process as described below) may advantageously reduce or eliminate the aforementioned contaminant and/or particle formation. In addition, pre-treating may eliminate impurities, thereby increasing the stability and/or reliability, and extending the useful life of the plurality of filaments.

The pre-treatment of the plurality of filaments depicted at 101 may generally begin at 103 where a hydrogen containing pre-treat gas is provided to a process chamber having the filaments disposed therein. The process chamber may be any type of process chamber that utilizes filaments as a heat and/or energy source, for example, such as a hot wire chemical vapor deposition (HWCVD) chamber or other similarly configured process chamber. In some embodiments, the process chamber may be similar to the process chamber described below with respect to FIG. 3.

The hydrogen containing pre-treat gas may be any non-reactive process compatible gas suitable to facilitate the pre-treatment of the plurality of filaments. For example, in some embodiments, the hydrogen containing pre-treat gas may comprise or may consist essentially of or may consist of hydrogen (H₂) gas, a mixture of hydrogen (H₂) gas and nitrogen (N₂) gas, ammonia (NH₃), hydrogen peroxide (H₂O₂), combinations thereof, or the like. In some embodiments, the hydrogen containing pre-treat gas may further comprise a dilutant gas, for example such as one or more of helium (He), Argon (Ar), or the like. In some embodiments the hydrogen containing pre-treat gas may consist essentially of or may consist of one or more of hydrogen (H₂) gas, a mixture of hydrogen (H₂) gas and nitrogen (N₂) gas, ammonia (NH₃), hydrogen peroxide (H₂O₂), or combinations thereof, mixed with a dilutant gas such as one or more of helium (He), Argon (Ar), or the like. The hydrogen containing pre-treat gas may be provided to the process chamber at any flow rate suitable to provide a sufficient amount of hydrogen to facilitate the pre-treatment of the plurality of filaments. For example, in some embodiments, the hydrogen containing pre-treat gas may be provided to the process chamber at a flow rate of up to about 10,000 sccm, or in some embodiments, about 10 sccm to about 3000 sccm.

Next, at 105, a current is flowed through the plurality of filaments to raise a temperature of the plurality of filaments to a first pre-treat temperature. The first pre-treat temperature may be any temperature suitable to facilitate at least a partial removal or out gassing of contaminants and/or impurities from the plurality of filaments. In some embodiments, the first pre-treat temperature may be dependent on the composition of the material used to fabricate the plurality of filaments. For example, in some embodiments, the first pre-treat temperature may be about 1000 to about 2500 degrees Celsius. The plurality of filaments may be maintained at the first pre-treat temperature for any period of time suitable facilitate a partial removal or out gassing of contaminants and/or impurities from the plurality of filaments. For example, in some embodiments, the plurality of filaments may be maintained at the first pre-treat temperature for a period of time of about 60 seconds to about 600 seconds. In any of the above embodiments, at least one of the temperature or time may be dependent on the materials used to fabricate the filaments and/or the configuration of the plurality of filament within the process chamber.

Next, at 107, the current flowing through the plurality of filaments may be reduced (including stopped) to cool the plurality of filaments to a second pre-treat temperature. The second pre-treat temperature may be any temperature sufficient to achieve desired filament properties and may be dependent on the composition of the material used to fabricate the plurality of filaments. For example, in some embodiments, the second pre-treat temperature may be about 1000 to about 2500 degrees Celsius. The plurality of filaments may be maintained at the second pre-treat temperature for any period of time for example, a period of time of about 60 to about 600 seconds.

The plurality of filaments may be cooled at any rate suitable to produce a desired microstructure to achieve the desired filament properties. For example, in some embodiments, the plurality of filaments may be cooled at a rate of about 100 to about 2000 degrees Celsius per minute. The plurality of filaments may be cooled via any mechanism suitable to achieve the desired cooling rate. For example, in some embodiments, the current may be gradually reduced continuously or in a number of steps. Alternatively, in some embodiments, the current may be shut off after the first temperature is maintained for a period of time, thereby allowing the plurality of filaments to cool.

In some embodiments, the pre-treatment of the plurality of filaments may be a cyclical process, wherein each cycle may include raising the plurality of filaments to the first pre-treat temperature followed by cooling the plurality of filaments to the second pre-treat temperature. The cycle may be performed any amount of times suitable to facilitate the pre-treatment process.

In addition to the above, additional process parameters, for example, such as in internal process chamber pressure, temperature, or the like, may be utilized to facilitate pre-treating the plurality of filaments. For example, the process chamber may be maintained at a pressure of less than about 10⁻⁹ mTorr (e.g., an ultra high vacuum) to about 10 Torr during the pre-treatment process. In addition, the process chamber may be maintained at any temperature suitable to facilitate pre-treating the plurality of filaments.

Although the pre-treatment process described herein is described in the context of being performed prior to a cleaning process, the pre-treatment of the plurality of filaments may be performed prior to any process, for example, such as a deposition process (e.g., a hot wire chemical vapor deposition (HWCVD) process, a chemical vapor deposition process (CVD), or the like), a nitridation process, or the like.

Alternatively or in combination with the optional pre-treatment of the plurality of filaments, a substrate to be processed or cleaned may also optionally be preheated, as shown at 102. The preheating of the substrate can occur prior to, at the same time as, or subsequent to the optional pre-treatment of the plurality of filaments. Preheating the substrate prior to performing a cleaning process (e.g. the cleaning process as described below) may facilitate a de-gassing and/or removal of contaminants from the substrate. In some embodiments, the substrate may be preheated in the same chamber as used for the cleaning process. Alternatively, in some embodiments, a preheat chamber different than that used for the cleaning process may be utilized (such as preheat chamber 350 discussed below with respect to FIG. 3). The inventors have observed that preheating the substrate in a different chamber than that used to perform the cleaning process may reduce or eliminate the incidence of contamination of the substrate with residual process byproducts from the cleaning process chamber and/or may reduce or eliminate the incidence of contamination of the cleaning process chamber with materials from the substrate.

The preheat chamber may be any type of chamber suitable to preheat the substrate 200 to a desired temperature, for example such as a dedicated preheat chamber, an annealing chamber, a deposition chamber, or the like. In some embodiments the preheat chamber may be a hot wire processing chamber or similarly configured chamber such as the chamber described below with respect to FIG. 3. In some embodiments, the preheat chamber may be one of a plurality of chambers coupled to a multi-chamber tool, for example such as a cluster tool or in-line processing tool.

The substrate 200 may be preheated to any temperature suitable to de-gas or remove contaminants from the substrate 200. For example, in some embodiments, the device 200 may be preheated to a temperature of up to about 500 degrees Celsius. The substrate may be preheated via any suitable heat source, for example, heating lamps or resistive heaters disposed within the chamber, heaters embedded within a substrate support, filaments of a hot wire source, or the like. In embodiments where the device 200 is preheated in a hot wire processing chamber, the hot wire source (e.g., the filaments) may be heated to a temperature of about 1000 to about 2500 degrees to facilitate preheating the device 200 to the desired temperature. Other temperatures may be used as appropriate for the substrate and the contaminants to be removed.

Referring to FIG. 2A, the substrate 200 may be any suitable substrate, such as a doped or un-doped silicon substrate, a III-V compound substrate, a gallium arsenide (GaAs) substrate, a silicon germanium (SiGe) substrate, an epi-substrate, a silicon-on-insulator (SOI) substrate, a display substrate such as a liquid crystal display (LCD), a plasma display, an electro luminescence (EL) lamp display, a light emitting diode (LED) substrate, a solar cell array, solar panel, or the like. In some embodiments, the substrate 200 may be a semiconductor wafer, such as a 200 or 300 mm semiconductor wafer. In some embodiments, the substrate 200 may be a very large scale integration (VLSI) device, a large scale glass substrate, for example, such as an about 1000 mm×1250 mm substrate or an about 2200 mm×2500 mm substrate.

In some embodiments, the substrate 200 may comprise one or more layers disposed in or on the substrate. In some embodiments, the one or more layers may be layers suitable for semiconductor fabrication, for example, oxide layers, nitride layers, high or low K dielectric layers, conductive layers, or the like. The layers may be formed via any suitable process, for example, such as physical vapor deposition, chemical vapor deposition, epitaxial growth, or the like. Alternatively or in combination, in some embodiments, one or more features (e.g., a via, a trench, a dual damascene structure, or the like) may be formed in the substrate 200 and/or one or more of the one or more layers disposed in or on the substrate. The features may be formed via any suitable process, for example such as an etch process. In addition, the substrate 200 may undergo additional processing prior to preheating, such as annealing, baking, cleaning, or the like.

In some embodiments, a layer 202 to be removed may be disposed atop a surface 204 of the substrate 200. Although described herein as a layer, the material to be removed may also be a partial layer, or may be islands of material disposed only upon portions of the surface 204. The layer 202 may comprise any materials that are to be removed from the substrate 200, for example, native oxide layers, nitride layers, silicon layers or the like, or prior process residues or contaminants, for example, such as carbon, silicon, nitrogen or oxygen containing contaminants, or the like.

The surface 204 of the substrate 200 may be any surface that requires cleaning prior to and/or subsequent to a process. For example, in some embodiments, for example, where the method 100 is utilized to clean contaminants from a substrate contact (e.g., a contact surface for gate stack application such as the fabrication of a complementary metal-oxide-semiconductor (CMOS) structure) the surface 204 may comprise one of silicides, such as nickel silicides, oxides, such as ruthenium oxide (RuO₂), silicon oxide (SiO₂), metal oxides, or the like.

If the substrate is preheated in a separate chamber, the substrate is moved to a cleaning chamber, such as a hot wire processing chamber, for cleaning the substrate. Next, at 104, a hydrogen containing gas may be provided to the cleaning chamber having the substrate disposed therein. The inventor has observed that by utilizing a hot wire chamber or similarly configured chamber, a higher density population of atomic hydrogen (e.g., such as 1.3 to about 3 times higher) may be produced, as compared to methods conventionally used in the semiconductor industry to produce atomic hydrogen. The hydrogen containing gas may comprise any gas or gases suitable to provide a high density of atomic hydrogen when decomposed. For example, in some embodiments, the hydrogen containing gas may comprise, consist essentially of, or consist of any of the gases or combination of gases discussed above with respect to the hydrogen containing pre-treat gas.

The hydrogen containing gas may be provided at any flow rate suitable to provide a needed amount of atomic hydrogen to clean the surface 204 of the substrate 200 and may be adjusted in accordance with the substrate 200 and/or cleaning chamber size. For example, in some embodiments, the hydrogen containing gas may be provided at a flow rate of about 1 to about 10,000 sccm. The cleaning chamber may be any type of process chamber having a plurality of filaments disposed therein, for example such as the process chamber described below with respect to FIG. 3.

Next, at 106, a current is flowed through the plurality of filaments disposed in the cleaning chamber to raise a temperature of the plurality of filaments to a process temperature. The current may be flowed through the plurality of filaments prior to, at the same time as, and/or subsequent to preheating the substrate (described above at 102) and/or providing the hydrogen containing gas to the cleaning chamber (described above at 104). The order of flowing the current through the plurality of filaments, preheating the substrate, and providing the hydrogen containing gas to the cleaning chamber may be varied dependent on the application (e.g., substrate composition, material to be removed, or the like). The plurality of filaments may be any suitable type of filaments disposed in any suitable type of cleaning chamber, for example such as the plurality of filaments disposed in the process chamber described below with respect to FIG. 3.

The process temperature may be any temperature suitable to achieve decomposition of the hydrogen containing gas to provide a desired density of atomic hydrogen and to facilitate cleaning the surface 204 of the substrate 200, as described below. For example, the process temperature may selected as appropriate for decomposing the particular hydrogen containing gas provided. The inventors have observed that by utilizing atomic hydrogen to facilitate the cleaning, the process temperature may advantageously be maintained at a lower temperature as compared to conventional cleaning processes (e.g., wet, thermal, or plasma cleaning processes). For example, in embodiments where the method is utilized to clean contaminants from a substrate contact, the process temperature may be about 10 to about 500 degrees Celsius.

Next, at 108, the surface 204 of the substrate 200 is cleaned by exposing the substrate 200 to the hydrogen atoms formed from the decomposition of the hydrogen containing gas for a period of time (e.g., until some or all of the materials or contaminants disposed on the substrate are removed). The inventor has observed that the highly reactive properties of atomic hydrogen facilitate removal of the layer 202, thereby cleaning the surface 204 of the substrate 200, as shown in FIG. 2B. By cleaning the surface 204 by exposing the substrate 200 to the hydrogen atoms as described above, the inventors have observed that the substrate 200 incurs less damage during the cleaning process as compared to conventional cleaning process, for example, such as cleaning processes that utilize a plasma to clean substrate surfaces, even where the same hydrogen containing gas might be provided but in a plasma state. In addition, the inventors have observed that utilizing the hydrogen atoms allows for the cleaning of the surface 204 of the substrate 200 while reducing or eliminating impurities and instances of oxidation of portions of the substrate, as compared to conventional cleaning processes (e.g., wet, thermal or plasma cleaning processes).

The period of time may be any amount of time needed to facilitate removal of the layer 202 to a satisfactory degree (e.g., completely removed, substantially removed, or the like) and may be varied in accordance to the composition of the layer 202, the substrate 200 size, or the like. In some embodiments, the removal of the layer 202 may be detected mechanically (via FTIR, SEM, TEM, XPS, SIMS, etc.) or electrically.

In some embodiments, the substrate 200 is disposed beneath, and directly exposed to, the plurality of filaments in the process chamber. Alternatively, in some embodiments, the substrate 200 may be separated from the plurality of filaments. For example, in some embodiments, a plate having a plurality of apertures (e.g., a gas distribution plate) may be disposed between the plurality of filaments and the substrate 200, for example, as described below with respect the plate 342 in FIG. 3. The plate may be fabricated from suitable process compatible materials. When present, the plate may reduce or eliminate thermal damage to the substrate and/or provide uniform distribution of hydrogen atoms across the substrate. In addition, the plate may further allow for independent temperature control of a portion of the chamber having the plurality of filaments disposed therein and a portion of the chamber having the device 200 disposed therein, thereby allowing each of the plurality of filaments and the substrate to be maintained at different temperatures, as described below. In another example, in some embodiments the atomic hydrogen may be formed remotely in a hot wire processing chamber and provided to a separate process chamber having the substrate 200 disposed therein. The substrate 200 may be positioned under the hot wire source, or under the plate 342, on a substrate support (e.g., substrate support 328 described below with respect to FIG. 3) in a static position or, in some embodiments, may move for dynamic cleaning as the substrate 200 passes under the plate 342.

In addition to the above, additional process parameters may be utilized to facilitate cleaning the surface 204 of the substrate 200. For example, the inventor has observed that the density of atomic hydrogen produced may be controlled by the pressure within the process chamber containing the substrate 200 (e.g. the hot wire processing chamber or separate process chamber). For example, in some embodiments the inner volume of the process chamber may be maintained at a pressure of about 1 mTorr to about 10 Torr and may be varied in accordance with the particular application. In addition, the substrate 200 may be maintained at any temperature suitable to facilitate cleaning the surface 204 of the substrate, for example, such as up to about 1000 degrees Celsius.

The substrate 200 may be maintained at the aforementioned temperature via any suitable heating mechanism or heat source, for example, such as resistive heaters (e.g., a heater embedded within a substrate support) heating lamps, or the like. In addition, the temperature may be monitored via any mechanism suitable to provide an accurate measurement of the temperature. For example, in some embodiments, the temperature may be monitored directly via one or more thermocouples, pyrometers, combinations thereof, or the like. Alternatively, or in combination, in some embodiments, the temperature may be estimated via a known correlation between a power provided to the heating mechanism and the resultant temperature. The inventors have observed that maintaining the substrate 200 at such temperatures provides additional energy to the process, which may facilitate a more complete decomposition of the hydrogen containing gas to form hydrogen atoms, thereby increasing the throughput and uniformity of the cleaning process.

After cleaning the surface 204 of the substrate 200 at 108, the method 100 generally ends and the substrate 200 may proceed for further processing. In some embodiments, additional processes such as additional layer depositions, etching, nitridation of layers, annealing (e.g., rapid thermal annealing RTA, etc.), or the like, may be performed on the substrate 200, for example, to form a semiconductor device on the substrate 200 or to prepare the substrate 200 for use in applications such as photovoltaic cells (PV), light emitting diodes (LED), or displays (e.g., liquid crystal display (LCD), plasma display, electro luminescence (EL) lamp display, or the like).

FIG. 3 depicts a schematic side view of a processing system (substrate cleaning system) 300 in accordance with embodiments of the present invention. In some embodiments, the processing system 300 includes a process chamber 301, a cleaning chamber 303 and, optionally, a preheat chamber 350. The process chamber 301 may be any type of process chamber having a plurality of filaments disposed therein, for example, such as a hot wire processing chamber (e.g., a HWCVD chamber or other suitable chamber having a hot wire source).

The process chamber 301 generally comprises a chamber body 302 having an internal volume 304 with an atomic hydrogen source 348 disposed therein. The atomic hydrogen source 348 is configured to provide atomic hydrogen to the surface of a substrate 330 (e.g., the device described above) during operation. The atomic hydrogen source includes a plurality of filaments 310 coupled to a power source 313 for providing current to heat the plurality of filaments to a temperature sufficient to produce atomic hydrogen from a hydrogen gas, provided for example, from a hydrogen gas source 346.

The plurality of wires 310 may comprise any number of wires suitable to provide a desired temperature profile within the process chamber. For example, in some embodiments, the plurality of wires may comprise 4 wires, 5 wires, 10 wires, 12 wires, 16 wires, or the like, although other numbers may be used depending upon the substrate size and chamber geometry, cleaning requirements, wire composition, gas composition, or the like. In some embodiments, the plurality of wires 310 may be a single wire routed back and forth across the internal processing volume 304. The wires 310 may have any thickness and/or density suitable to provide a desired density of atomic hydrogen within the process chamber 300. For example, in some embodiments, the diameter of each wire 310 may be selected to control the surface area of the wire. For example, in some embodiments, the wires 310 may have a diameter of about 0.5 mm to about 0.75 mm. In addition, in some embodiments, the density of each wire may be varied dependent on the application (e.g., substrate composition, material to be removed, or the like).

The wires 310 may be fabricated from any suitable process compatible conductive material, for example, such tungsten (W), tungsten trioxide (WO₃), tantalum (Ta), tantalum pentoxide (Ta₂O₅), iridium (Ir), nickel-chrome (NiCr), palladium (Pd), or the like. In some embodiments, the wires 310 may further include a dopant, for example such as silicon (Si). In such embodiments, the wires 310 may comprise up to about 50% silicon. The inventors have observed that the doped materials may provide improved properties as compared to undoped materials, for example, such as a longer useful life, increased mechanical and thermal stability, improved reliability, and increased stiffness to reduce sagging. In some embodiments, the addition of the dopants may improve the mechanical, thermal, and electrical stability of the wires 310 in high temperature processing applications (e.g., up to about 2500 degrees Celsius), for example, deposition processes, nitrogen or hydrogen treatments, or pre-cleaning processes.

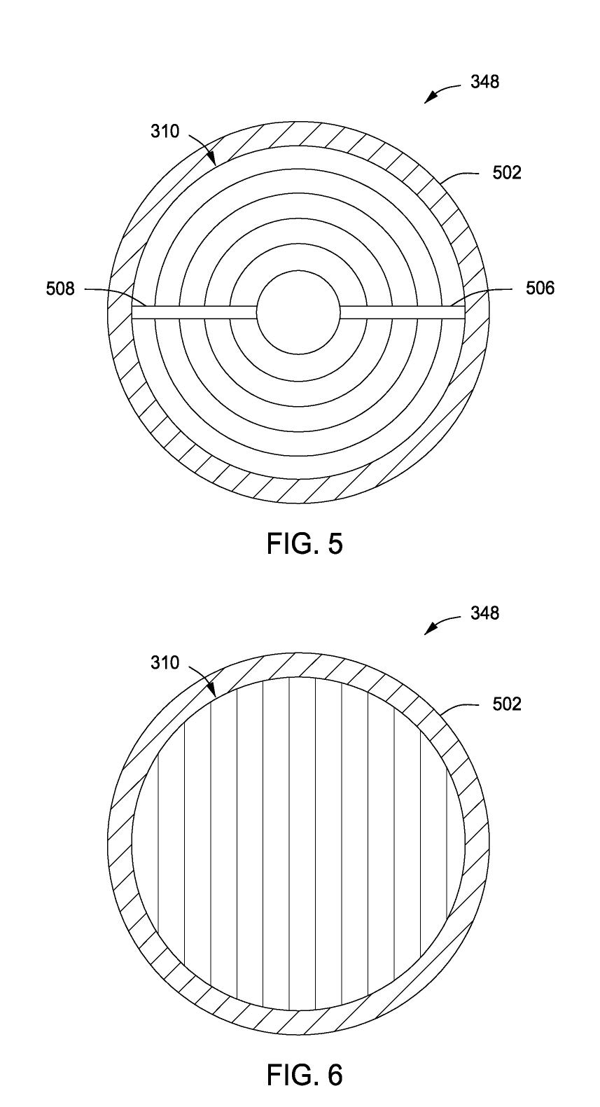

Each wire 310 is clamped in place by one or more support structures to keep the wire taught when heated to high temperature, and to provide electrical contact to the wire. In some embodiments, a distance between each wire 310 (i.e., the wire to wire distance 336) may be selected to provide a desired density of atomic hydrogen within the process chamber process chamber 300. For example, in some embodiments, the wire to wire distance 336 may be dependent on the number of wires (and therefore, total surface area provided by all of the wires). The wire to wire distance may be uniform as between all wires or may vary as between different sets of wires. For example, the location and/or spacing between the wires 310 may be controlled to provide a desired temperature profile with in the process chamber. The inventors have observed that controlling the location and spacing of the wires 310 facilitates control over properties such as hydrogen radical density and distribution, uniform cooling across the process chamber (e.g., proximate process chamber walls and throughout the inner volume of the process chamber) and the like. In some embodiments, the wire to wire distance 336 may be about 20 mm to about 60 mm. Wires may be configured in any manner suitable to provide a desired temperature profile within the process chamber, for example, such as described below with respect to FIGS. 5-7.

A power supply 313 is coupled to the wire 310, for example via one or more terminals, to provide current to heat the wire 310. A substrate 330 may be positioned under the hot wire source (e.g., the wires 310), for example, on a substrate support 328. The substrate support 328 may be stationary for static cleaning, or may move (as shown by arrow 305) for dynamic cleaning as the substrate 330 passes under the hot wire source. In some embodiments, a distance between each wire 310 and the substrate 330 (i.e., the wire to substrate distance 340) may be selected to facilitate a particular process (e.g., the inventive method 100 described above) being performed in the process chamber 300. For example, in some embodiments, the wire to substrate distance 340 may be about 10 to about 300 mm.

The chamber body 302 further includes one or more gas inlets (one gas inlet 332 shown) coupled to a hydrogen gas source 346 to provide the cleaning gas and one or more outlets (two outlets 334 shown) to a vacuum pump to maintain a suitable operating pressure within the process chamber 300 and to remove excess process gases and/or process byproducts. The gas inlet 332 may feed into a showerhead 333 (as shown), or other suitable gas distribution element, to distribute the gas uniformly, or as desired, over the wires 310.

In some embodiments, the substrate 330 may be separated from the hot wire source (e.g., the wires 310), via a gas distribution apparatus 341, for example, such as a plate 342 having a plurality of through holes 344 configured to distribute the gas (e.g. the atomic hydrogen described above) in a desired manner to the substrate 330. For example, the number of through holes, patterns and dimensions of the plurality of through holes 344 may be varied in accordance with the particular application. For example, in some embodiments, the plurality of through holes 344 may be configured such that the plate 342 may have about 10% to about 50% open area. In some embodiments, each of the plurality of through holes may have a diameter of about 1 mm to about 30 mm.

In addition to distributing the gas, when present, the gas distribution apparatus 341 may prevent a broken or failed wire 310 from contacting the substrate 330. In some embodiments, a distance from the gas distribution apparatus 341, or plate 342, to the substrate 330 may be any distance suitable to provide a desired density of atomic hydrogen to the substrate 330. For example, in some embodiments, the gas distribution apparatus 341 to substrate distance 331 may be about 10 to about 200 mm.

The cleaning chamber 303 generally comprises a chamber body 305 defining an inner volume 307. The substrate support 328 may be positioned within the inner volume 307. In some embodiments, the cleaning chamber 303 may comprise one or more heaters (not shown) to facilitate heating the substrate. When present, the one or more heaters disposed in the cleaning chamber 303 may facilitate pre-heating the substrate, for example, such as described above.

In some embodiments, one or more shields 320 may be provided to minimize unwanted deposition of materials on interior surfaces of the chamber body 302. The shields 320 and chamber liners 322 generally protect the interior surfaces of the chamber body 302 from undesirably collecting deposited materials due to the cleaning process and/or process gases flowing in the chamber. The shields 320 and chamber liners 322 may be removable, replaceable, and/or cleanable. The shields 320 and chamber liners 322 may be configured to cover every area of the chamber body 302 that could become coated, including but not limited to, around the wires 310 and on all walls of the coating compartment. Typically, the shields 320 and chamber liners 322 may be fabricated from aluminum (Al) and may have a roughened surface to enhance adhesion of deposited materials (to prevent flaking off of deposited material). The shields 320 and chamber liners 322 may be mounted in the desired areas of the process chamber, such as around the hot wire sources, in any suitable manner. In some embodiments, the source, shields, and liners may be removed for maintenance and cleaning by opening an upper portion of the process chamber 300. For example, in some embodiments, the a lid, or ceiling, of the process chamber 300 chamber may be coupled to the chamber body 302 along a flange 338 that supports the lid and provides a surface to secure the lid to the body of the process chamber 300.

In some embodiments, a preheat chamber 350 may be provided to preheat the substrate. The preheat chamber may be any suitable chamber having a heat source 352 for providing heat to the substrate 330 disposed in the preheat chamber 350. The preheat chamber 350 may be coupled directly to the process chamber 300, for example as part of an inline substrate processing tool, or may be coupled to the process chamber 300 via one or more intervening chambers, such as a transfer chamber of a cluster tool. An example of a suitable inline substrate processing tool is described in US Patent Application Publication 2011/0104848A1, by D. Haas, et al., published May 5, 2011, now U.S. Pat. No. 8,117,987, issued Feb. 21, 2012.

A controller 306 may be coupled to various components of the process chamber 300, and optionally to the chamber 301 and/or the preheat chamber 350, to control the operation thereof. Although schematically shown coupled to the process chamber 300, the controller may be operably connected to any component that may be controlled by the controller, such as the power supply 313, the gas supply 346 coupled to the inlet 332, a vacuum pump and or throttle valve (not shown) coupled to the outlet 334, the substrate support 328, and the like, in order to control the cleaning process in accordance with the methods disclosed herein. The controller 306 generally comprises a central processing unit (CPU) 308, a memory 312, and support circuits 310 for the CPU 308. The controller 306 may control the HWCVD process chamber 300 directly, or via other computers or controllers (not shown) associated with particular support system components. The controller 306 may be one of any form of general-purpose computer processor that can be used in an industrial setting for controlling various chambers and sub-processors. The memory, or computer-readable medium, 312 of the CPU 308 may be one or more of readily available memory such as random access memory (RAM), read only memory (ROM), floppy disk, hard disk, flash, or any other form of digital storage, local or remote. The support circuits 310 are coupled to the CPU 308 for supporting the processor in a conventional manner. These circuits include cache, power supplies, clock circuits, input/output circuitry and subsystems, and the like. Inventive methods as described herein may be stored in the memory 312 as software routine 314 that may be executed or invoked to turn the controller into a specific purpose controller to control the operation of the process chamber 300 in the manner described herein. The software routine may also be stored and/or executed by a second CPU (not shown) that is remotely located from the hardware being controlled by the CPU 308.

In some embodiments, the process chamber 301 and the cleaning chamber 303 may be coupled to one another or constructed integrally with one another to form a unitary process chamber (e.g., such as shown in FIG. 3). Alternatively, in some embodiments, the process chamber 301 and the cleaning chamber 303 may be separate chambers, such as shown in FIG. 3A. In such embodiments, the process gas (e.g., the hydrogen containing gas) may be heated by the wires 301 remotely and the resultant atomic hydrogen may be provided to the cleaning chamber via, for example, a conduit 354. In some embodiments, the conduit 354 may provide the atomic hydrogen to a cavity or plenum 356 disposed above the gas distribution apparatus 341 and then distributed to the inner volume 307 of the cleaning chamber 307 via the plurality of through holes 344.

In some embodiments, the atomic hydrogen source 348 may a part of the body of the process chamber 300. Alternatively, in some embodiments, the atomic hydrogen source 348 may be integrated within a removable lid, such as shown in FIG. 4. For example, FIG. 4 depicts a schematic side view of a process chamber 412 having a chamber body 406 and a removable lid 401 coupled to the chamber body 406. Integrating the atomic hydrogen source 348 within the removable lid 401 allows for the atomic hydrogen source 348 to be easily removed or replaced, thereby allowing differently configured atomic hydrogen sources to be utilized with a single process chamber. In addition, the removable lid 401 may be adapted to be coupled to pre-existing process chambers not originally configured for use with the atomic hydrogen source 348. For example, the inventors have observed that some conventional process chambers that are configured to receive a plasma from a remote source may receive an insufficient hydrogen radical flux from the plasma source to perform some processes. Providing a modular atomic hydrogen source 348 (e.g., the atomic hydrogen source 348 integrated within the removable lid 401) would allow for the atomic hydrogen source 348 to be installed when needed, thereby providing a desired density of hydrogen radicals to perform a desired process, thus providing a process chamber with increase process flexibility.

In some embodiments, the removable lid 401 may comprise a body 402 having a recess 408 formed in a lower surface 410 of the body 402. The body 402 interfaces with the chamber body 406 to facilitate removably coupling the removable lid 401 to the process chamber 412 such that the atomic hydrogen source 348 may be disposed in a desired position with respect to the process chamber 412 (e.g. such as above a substrate 418 disposed on a substrate support 422 as shown in FIG. 4). The process chamber 412 may be any process chamber 412 suitable for performing semiconductor processes, for example, a process chamber configured for deposition processes such as chemical vapor deposition (CVD), physical vapor deposition (PVD), or the like, or the process chamber 300 described above. Exemplary process chambers may include the ENDURA® platform process chambers, or other process chambers, available from Applied Materials, Inc. of Santa Clara, Calif. Other suitable process chambers may similarly be used.

In some embodiments, a showerhead 404 (e.g., similar to showerhead 333 described above with respect to FIG. 3) may be disposed in an inner portion 414 of the recess 408 and a gas distribution apparatus 420 (e.g., similar to gas distribution apparatus 341 described above with respect to FIG. 3) may be disposed in a outer portion 416 of the recess 408. The wires 310 may be disposed between the showerhead 404 and gas distribution apparatus 420. The inlet 332 is disposed through the body 402 to provide one or more process gases (e.g., the hydrogen containing gas discussed above) from the hydrogen gas source 346 to the showerhead 404.

The showerhead 404 and gas distribution apparatus 420 may be fabricated from any process compatible material, for example, such as aluminum (Al), quartz (SiO₂), or the like. In addition, each of the showerhead 404 and gas distribution apparatus 420 may be configured in accordance with the specific application or materials being processed within the process chamber 412. For example, the size, shape, distribution and patterns of distribution holes formed in each of the showerhead 404 and gas distribution apparatus 420 may be varied to accommodate for the particular application.

In some embodiments, a liner 406 may disposed on the exposed surfaces of the recess 408. When present, the liner 406 may protect the exposed surfaces of the recess during processing. In addition, in some embodiments, the liner 406 may reduce or eliminate recombination of the hydrogen atoms generated within the atomic hydrogen source 348. The liner 406 may be fabricated from any process compatible material suitable to perform the aforementioned functions and may be dependent on the specific application or materials being processed within the process chamber 412. For example, in some embodiments, the liner 406 may be fabricated from a metal such as aluminum (Al), quartz (SiO₂), or the like, or a metal oxide such as aluminum oxide (Ai₂O₃) or the like. In embodiments where the liner 406 is fabricated from a metal, the liner 406 may further comprise a coating, for example such as titanium oxide (TiO), thorianite (ThO₂), or the like. When present, the coating may reduce recombination of the hydrogen atoms and/or increase heat reflectance and reduce heat absorption into the liner 406, thereby facilitating the process chamber to be maintained at a desired temperature.

In any of the above embodiments of the atomic hydrogen source 348 as described above, the wires 310 may be configured in any manner to provide a suitable temperature profile within the process chamber. For example, referring to FIG. 5, in some embodiments, the wires 310 may be configured in a concentric ring pattern. In some embodiments, the wires 310 may be supported by one or more support structures, for example, such as a support ring 502, one or more support arms 506, 508, or the like. In some embodiments, the wires 310 may be linearly disposed parallel to one another, such as shown in FIG. 6.

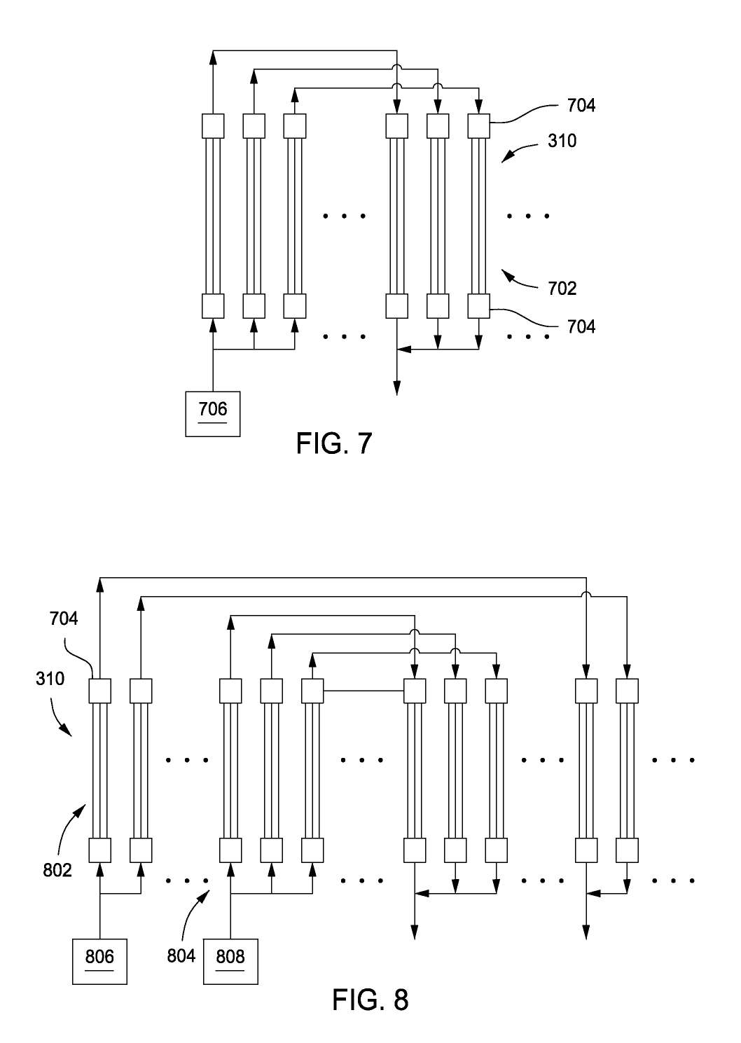

In some embodiments, the wires 310 may be configured to provide heating zones within the process chamber. For example, in some embodiments, the wires 310 may be configured in a single zone 702, such as shown in FIG. 7. In such embodiments, the wires 310 may be electrically coupled to one another in parallel and provided power from a single power source 706. In some embodiments, a wire clamp 704 may be disposed at each end of each of the wires 310 to support the wires 310 and may provide a terminal to couple the wires 310 to the power source 706. In some embodiments, each wire clamp 704 may support more than wire, for example, three wires 310 as shown in FIG. 7.

Alternatively, in some embodiments, the wires 310 may be configured in a plurality of zones, such as shown in FIG. 8. The wires 310 may be configured in any number of zones, for example such as two zones (first zone 802 and second zone 804) such as shown in FIG. 8. In some embodiments, each zone of the plurality of zones may be coupled have a separate power source (e.g., power sources 806, 808 coupled to first zone 802 and second zone 804, respectively) to allow for independent adjustment of each zone of the plurality of zones.

Thus, methods and apparatus for cleaning a surface of a substrate have been provided herein. Embodiments of the inventive process may advantageously allow for removal of contaminants or undesired layers from a substrate while causing less damage to the substrate as compared to conventional cleaning processes utilizing, for example, one or more of a plasma, a high temperature treatment or a fluorine based chemistry.

While the foregoing is directed to embodiments of the present invention, other and further embodiments of the invention may be devised without departing from the basic scope thereof.

1. A method of cleaning a surface of a substrate, comprising:
providing a hydrogen containing gas to a first chamber having a plurality of filaments disposed therein;
flowing a current through the plurality of filaments to raise a temperature of the plurality of filaments to a process temperature sufficient to decompose at least some of the hydrogen containing gas; and
cleaning the surface of the substrate by exposing the substrate to hydrogen atoms formed from the decomposed hydrogen containing gas.

2. The method of claim 1, wherein the hydrogen containing gas comprises hydrogen (H₂), hydrogen (H₂) and nitrogen (N₂), or ammonia (NH₃).

3. The method of claim 1, wherein cleaning the surface of the substrate comprises:
moving the substrate linearly through a region containing the hydrogen atoms to expose the substrate to the hydrogen atoms.

4. The method of claim 1, further comprising:
preheating the substrate prior to cleaning the surface of the substrate.

5. The method of claim 4, further comprising:
preheating the substrate in a preheat chamber; and
transferring the substrate out of the preheat chamber prior to cleaning the surface of the substrate.

6. The method of claim 4, further comprising:
preheating the substrate in a cleaning chamber; and
cleaning the surface of the substrate in the cleaning chamber.

7. The method of claim 6, wherein the cleaning chamber and the first chamber are the same chamber.

8. The method of claim 1, further comprising:
disposing the substrate in a cleaning chamber different than the first chamber; and
providing the hydrogen atoms formed in the first chamber to the cleaning chamber.

9. The method of claim 1, further comprising, prior to providing the hydrogen containing gas to the first chamber, pre-treating the plurality of filaments by:
providing a hydrogen containing pre-treat gas to the process chamber;
heating the plurality of filaments to a first pre-treat temperature; and
cooling the plurality of filaments to a second pre-treat temperature.

10. The method of claim 9, wherein the hydrogen containing pre-treat gas comprises hydrogen (H₂) gas, hydrogen (H₂) and nitrogen (N₂), or ammonia (NH₃).

11. The method of claim 9, further comprising:
repeatedly heating the plurality of filaments to the first pre-treat temperature and cooling the plurality of filaments to the second pre-treat temperature.

12. A substrate cleaning system, comprising:
a process chamber having an internal volume;
a substrate support disposed in the internal volume of the process chamber to support a substrate to be cleaned in the process chamber;
an atomic hydrogen source configured to provide atomic hydrogen to the surface of the substrate during operation, the atomic hydrogen source comprising a plurality of filaments and a terminal to couple the plurality of filaments to a power source to heat the plurality of filaments to a temperature sufficient to produce atomic hydrogen from a hydrogen gas; and
a hydrogen gas source coupled to the atomic hydrogen source to provide hydrogen gas to the atomic hydrogen source.

13. The substrate cleaning system of claim 12, further comprising:
a gas distribution plate disposed between the atomic hydrogen source and the internal volume of the process chamber such that atomic hydrogen provided by the atomic hydrogen source passes through the gas distribution plate to reach the internal volume of the process chamber.

14. The substrate cleaning system of claim 12, wherein the atomic hydrogen source is separate from the process chamber.

15. The substrate cleaning system of claim 12, wherein the atomic hydrogen source is disposed within the process chamber.

16. The substrate cleaning system of claim 12, wherein the atomic hydrogen source is integrated into a process chamber lid that is removably coupleable to the process chamber.

17. The substrate cleaning system of claim 16, wherein the process chamber lid comprises:
a body having a recess formed in a lower surface of the body, wherein the plurality of filaments are disposed within the recess;
a gas inlet disposed above the plurality of filaments to provide the hydrogen gas to the plurality of filaments; and
a gas distribution plate coupled to the body beneath the plurality of filaments, the gas distribution plate having a plurality of holes to fluidly couple the recess to the internal volume.

18. The substrate cleaning system of claim 17, wherein the process chamber lid further comprises a liner disposed on the inner surface of the recess.

19. The substrate cleaning system of claim 12, wherein the plurality of filaments comprise tantalum (Ta), tungsten (W), or iridium (Ir).

20. The substrate cleaning system of claim 19, wherein the plurality of filaments further comprise a silicon (Si) dopant.
